(19) United States
(12) Patent Application Publication
(10) Pub. No.: US 2007/0113161 A1
(43) Pub. Date: May 17, 2007

(54) CASCADED RADIX ARCHITECTURE FOR HIGH-SPEED VITERBI DECODER

(75) Inventors: Srinivas Lingam, Dallas, TX (US); Seok-Jun Lee, Allen, TX (US); Anuj Batra, Dallas, TX (US); Manish Goel, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/557,208

(22) Filed: Nov. 7, 2006

Related U.S. Application Data
(60) Provisional application No. 60/736,368, filed on Nov. 14, 2005.

(51) Int. Cl. H03M 13/03

(52) U.S. Cl. 714/796

(57) ABSTRACT

A Viterbi decoder includes a branch metric unit for generating branch metrics between two states at two different time periods, a traceback unit, a traceback memory and an add-compare-select circuit. The add-compare-select circuit includes a plurality of cascaded add-compare-select sub-circuits, each add-compare-select sub-circuit calculating a path metric responsive to a plurality of branch metrics from the branch metric unit and a plurality of pre-calculated path metrics, where at least one of the add-compare-select sub-circuits receives a set of pre-calculated path metrics from another one of the add-compare-select sub-circuits.

### CROSS-REFERENCE TO RELATED APPLICATIONS

This application claims the benefit of the filing date of copending provisional application U.S. Ser. No. 60/736,368, filed Nov. 14, 2005, entitled “Cascaded Radix Architecture For High-Speed Viterbi Decoder”

### STATEMENT OF FEDERALLY SPONSORED RESEARCH OR DEVELOPMENT

Not Applicable

### BACKGROUND OF THE INVENTION

1. Technical Field

This invention relates in general to communications and, more particularly, to a Viterbi decoder using a cascaded add-compare-select (ACS) circuit.

2. Description of the Related Art

Many electronic devices use error correction techniques in conjunction with data transfers between components and/or data storage. Error correction is used in many situations, but is particularly important for wireless data communications, where data can easily be corrupted between the transmitter and the receiver. In some cases, errant data is identified as such and retransmission is requested. Using more robust error correction schemes, however, errant data can be reconstructed without retransmission.

One popular error correction technique uses Viterbi decoding to detect and correct errors in a data stream from a convolution encoder. A Viterbi decoder determines costs associated with multiple possible paths between nodes. After a specified number of stages, the node with the minimum associated cost is chosen, and a path is traced back through the previous stages. The data is decoded based on the selected path. To calculate the path with the lowest cost, add-compare-select (ACS) units are used.

As wireless communication becomes more popular, faster speeds are very desirable. Accordingly, higher speeds are required from the Viterbi decoders. As an example, current 802.1 n wireless LAN devices have data rates of 320 Mbps (mega-bits per second) up to 640 Mbps, while MB-OFDM (Multi-Band Orthogonal Frequency-Division Multiplexing) devices have a current maximum data rate of 480 Mbps. An ACS having a Radix-2 architecture, which processes one bit per clock, requires a clock rate of 320 MHz to maintain a 320 Mbps data stream or a clock rate of 640 MHz to maintain a 640 Mbps data stream. The clock rate can be reduced if a Radix-4 architecture is used, because a Radix-4 architecture processes two bits per clock. Similarly, a Radix-8 architecture processes three bits per clock and a Radix-16 architecture processes four bits per clock. Unfortunately, as the radix is increased, the gate count complexity is exponentially increased, resulting in very complex and costly circuits.

Therefore, a need has arisen for a high-speed Viterbi decoder using an ACS unit with a lower gate count.

### BRIEF SUMMARY OF THE INVENTION

In the present invention, a Viterbi decoder includes a branch metric unit for generating branch metrics between two states at two different time periods, a traceback unit, a traceback memory and an add-compare-select circuit. The add-compare-select circuit includes a plurality of cascaded add-compare-select sub-circuits, each add-compare-select sub-circuit calculating a path metric responsive to a plurality of branch metrics from the branch metric unit and a plurality of pre-calculated path metrics, where at least one of the add-compare-select sub-circuits receives a set of pre-calculated path metrics from another one of the other add-compare-select sub-circuits.

The present invention provides an architecture by which the number of information bits processed per clock cycle can be increased without increasing the number of adders/bit processed per clock cycle. This can greatly reduce the cost and complexity of the Viterbi decoder.

### BRIEF DESCRIPTION OF THE SEVERAL VIEWS OF THE DRAWINGS

For a more complete understanding of the present invention, and the advantages thereof, reference is now made to the following descriptions taken in conjunction with the accompanying drawings, in which:

FIG. 1 is a example of a data communication connection used in the prior art;

FIG. 2 is a block diagram of a conventional data encoder;

FIG. 3 is a state diagram of the encoder of FIG. 2;

FIG. 4 is a trellis diagram showing data transitions;

FIG. 5 is a trellis diagram showing the decoding of the data from the encoder of FIG. 2;

FIGS. 6a through 6d are trellis diagrams showing the calculation of path metrics through the trellis diagram;

FIG. 7 illustrates a prior art Viterbi decoder;

FIGS. 8a through 8d illustrate operation of the prior art Viterbi decoder of FIG. 7 with respect to a Radix-2, a Radix-4, a Radix-8 and a Radix-16 ACS sub-unit;

FIG. 9a, 9b and 9c illustrate block diagrams of Radix-2, Radix-4 and Radix-4 fast ACS units;

FIG. 10 illustrates a Viterbi decoder with a cascaded ACS unit;

FIG. 11 illustrates an implementation of the Viterbi decoder of FIG. 10 using two Radix-4 ACS units;

FIG. 12 illustrates a first implementation of a Viterbi decoder of FIG. 10 for processing five bits per clock cycle.

FIG. 13 illustrates a second implementation of a Viterbi decoder of FIG. 10 for processing five bits per clock cycle.

FIG. 14 illustrates a first implementation of a Viterbi decoder of FIG. 10 for processing six bits per clock cycle.

FIG. 15 illustrates a second implementation of a Viterbi decoder of FIG. 10 for processing six bits per clock cycle.

### DETAILED DESCRIPTION OF THE INVENTION

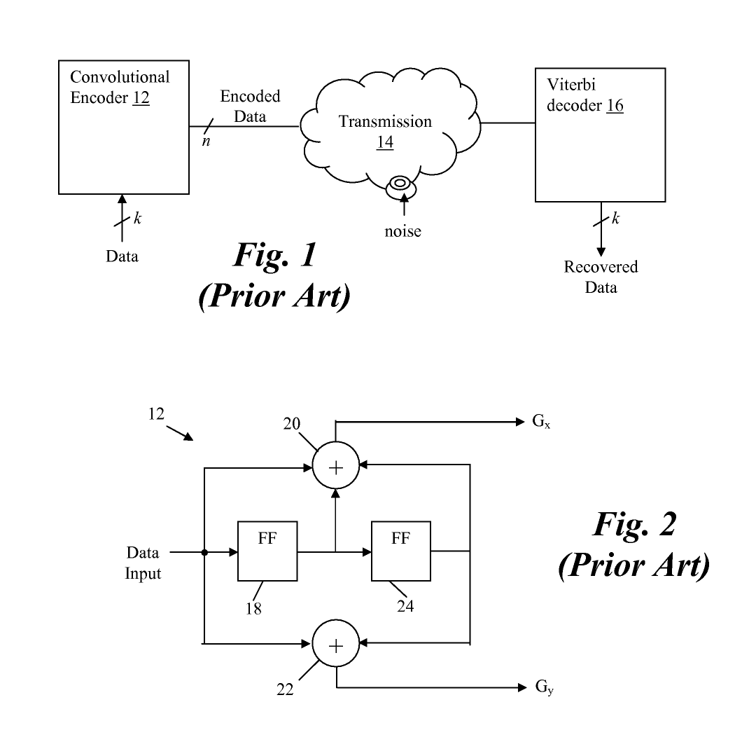

The present invention is best understood in relation to FIGS. 1-15 of the drawings, like numerals being used for like elements of the various drawings.

FIG. 1 illustrates a general block diagram of communications between a data source and destination using convolutional encoding. At the source, k-bit data is received by a convolutional encoder 12. The convolutional encoder 12 generates an n-bit encoded data output based on the received data. The encoded data is transmitted to the destination through a transmission medium 14. During transmission, noise may be added to the encoded data, thereby corrupting some of the output. At the destination, the possibly corrupted data is received by Viterbi decoder 16. The Viterbi decoder recovers the original data; even if the encoded data is corrupted, the Viterbi decoder is able to recover the original data in many situations.

For illustration of convolutional encoding, an example using a k=1, n=2 structure is shown in FIG. 2. The encoder 12 receives the data to be encoded into a flip-flop 18 and two modulo-2 adders 20 and 22. The output of flip-flop 18 is also received by an input of modulo-2 adder 20. The output of flip-flop 18 is also coupled to the input of flip-flop 24. The output of flip-flop 24 is coupled to an input of modulo-2 adder 20 and an input of modulo-2 adder 22. The encoded output XY of the convolution encoder 12 is the output of modulo-2 adder 20 (X) and modulo-2 adder 22 (Y).

The convolutional encoder 12 has a constraint length (K) of 3, meaning that the current output is dependent upon the last three inputs. The dependency on previous values to affect the encoded data output allows the Viterbi decoder to reconstruct the data despite transmission errors. Convolutional decoders are often classified as (n,k,K) encoders; hence the encoder shown in FIG. 2 would be a (2,1,3) encoder. The connection vectors, which define the connections between the shift register formed by flip-flops 18 and 24, for the encoder shown in FIG. 2 are “111” for modulo-2 adder 20 and “101” for modulo-2 adder 22.

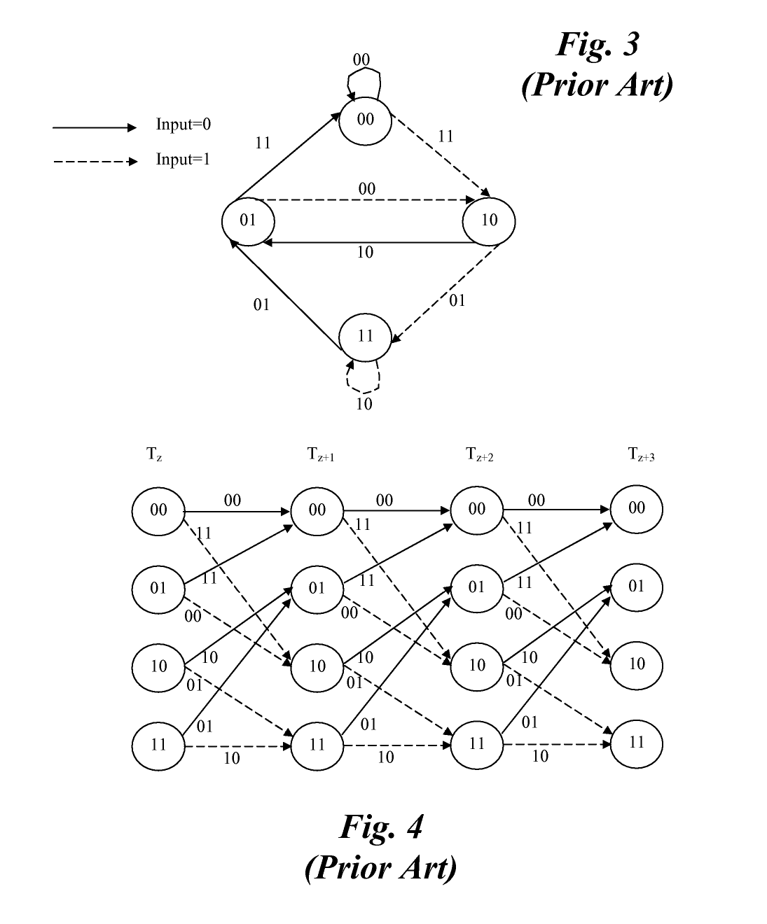

The “state” of the encoder 12 is defined as the outputs of the flip-flops 18 and 24. Thus the state of encoder 12 can be notated as “(output of FF 18, output of FF 24)”. A state diagram for the encoder of FIG. 2 is shown in FIG. 3. Each of the four possible states (00, 01, 10 and 11) is shown within a circle. Transitions between states are shown responsive to a data input of “0” (solid line) or a data input of “1” (dashed line). The two-bit value above the transition line is the resulting output XY. Thus, from a state of “00”, an input of “0” will result in a return to “00” with an output of “00”. An input of 1 will result in a transition to “10” and an output of “11”.

The state diagram of FIG. 3 shows the transitions from any state at any given moment. In FIG. 4, a “trellis” diagram is used to shown the transitions over time. From an arbitrary time, T_{z}, the trellis diagram of FIG. 4 shows the possible state transitions and outputs responsive to a given data input.

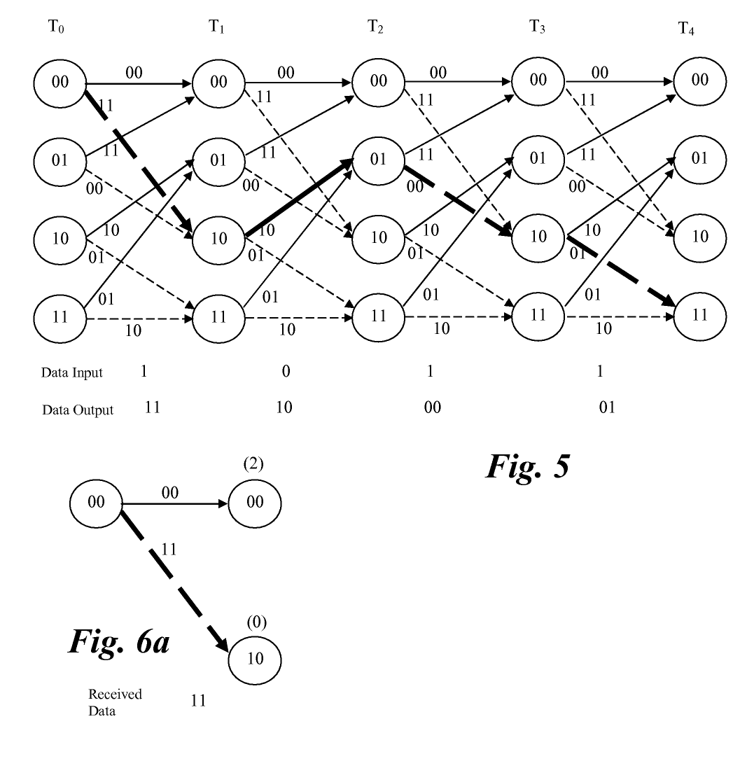

FIG. 5 shows an example of a path through the trellis using a data input sequence of “1011” from an initial state of “00”. The initial data input “1” causes a transition from state “00” to state “10” and an encoded output of “11”. The next data input, “0”, causes a transition from state “10” to state “01” and an encoded output of “10”. The following data input, “1”, causes a transition from state “01” to “10” and an encoded output of “00”. The final data input, “1”, causes a transition from state “10” to state “11” and an encoded output of “01”.

The encoded output “11 10 00 01” will be transmitted to a receiving device with a Viterbi decoder. The two-bit encoded outputs are used to reconstruct the data. By convention, a data transmission begins in state “00”. Hence, the first encoded output “11” would signify that the first input data bit was a “1” and the next state was “10”. Assuming no errors in transmission, the data input could be determined by state diagram of FIG. 2 or the trellis of FIG. 3.

However, in real-world conditions, the encoded data may be corrupted during transmission. In essence, the Viterbi decoder 16 traces all possible paths, maintaining a “path metric” for each path, which accumulates differences (“branch metrics”) between the each of the encoded outputs actually received and the encoded outputs that would be expected for that path. The path with the lowest path metric is the maximum likelihood path.

The Viterbi decoder 16 can also trace all possible paths, accumulating the correlation between the each of the encoded outputs actually received and the encoded outputs that would be expected for that path. If this correlation metric is used, the path with the highest path metric is the maximum likelihood path, but this new metric does not change the ACS circuit data-path and hence the same ACS circuit and sub-circuits can be used.

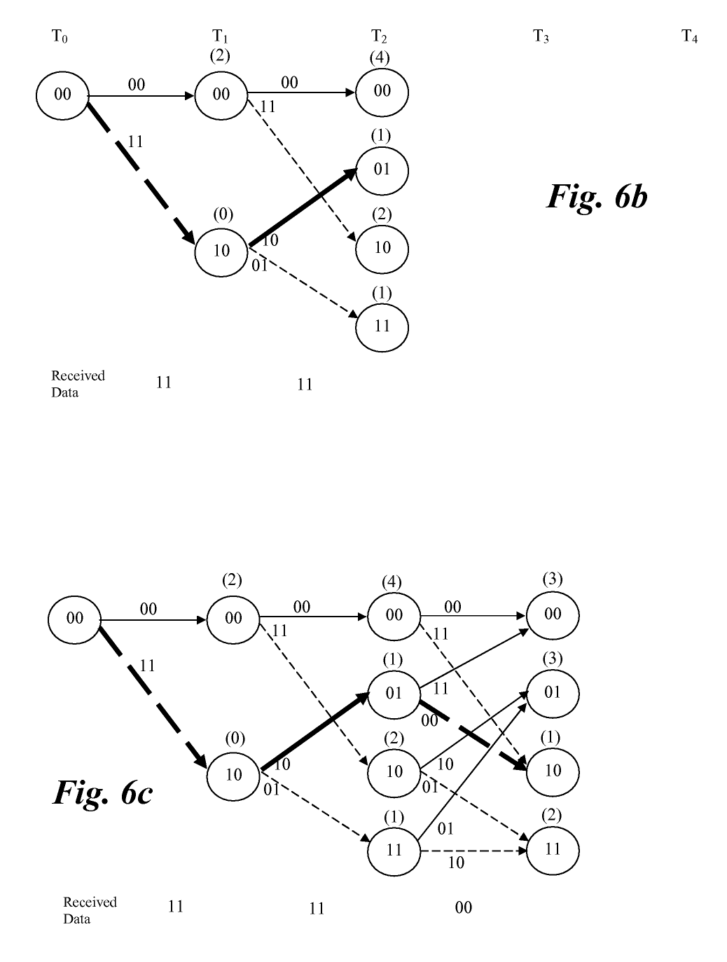

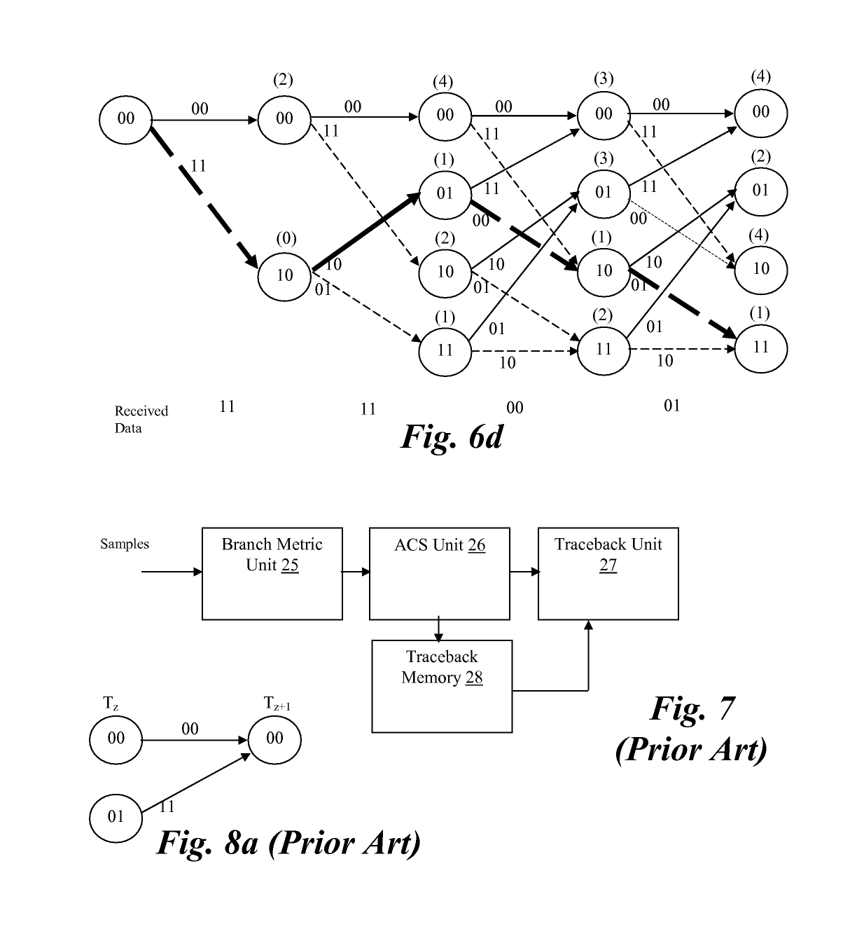

FIG. 6a illustrates computation of the branch metrics for the transition from the initial state of “00”. In this case, an “11” was received. With two-bit outputs, a “Hamming distance” may be used to calculate the branch metric. The Hamming distance is the sum of exclusive-or operations on respective bits of the received output and the expected output. For the path assuming a “0” input, the branch metric between the received encoded output (“11”) and the expected encoded output (“00”) is two. For the path assuming a “1” input, the branch metric between the received encoded output (“11”) and the expected encoded output (“11”) is zero. Hence the path metric at state “00” at time T₁ is two and the path metric at state “10” at time T₁ is zero. The path metrics are shown above the states in the diagram.

FIG. 6b illustrates the path through time T₂. In this example, it is assumed that there is a data transmission error, and the received encoded output (symbol) is “11” rather than “10”. Hence, at T₂, the branch metric between state “00” at T₁ and state “00” at T₂ is two; when added to the previous path metric of two at state “00” at T₁, the path metric is four for state “00” at T₂. Similarly, at T₂, the path metric is one for state “01”, two for state “10” and one for state “11”.

FIG. 6c illustrates the path through time T₃. At this point, two potential paths are entering each state. For each state, the branch metric is computed for each path entering the state, and the path with the lowest path metric is chosen (the “surviving path”). If two paths have the same path metric (such as state “01” at T₃), a path can be chosen randomly or deterministically (such as by always choosing the upper path).

FIG. 6d shows the path through time T₄. At this point, the actual path through states “10 01 10 11” has the lowest path metric. If the example sequence were longer, the path metrics for all other paths would increase as the path metric for the actual path remained the same (assuming no additional errors). When the end of a path is reached, the most likely path is determined through a process called “traceback”.

As can be seen in FIGS. 6a-d, for each time period, a branch metric calculation and path metric calculation must be performed for each path entering a state. Further, a comparison must be performed to determine the surviving state.

FIG. 7 illustrates a general block diagram of a Viterbi decoder 16. The Viterbi decoder has four main sections. A branch metric unit 25 that receives the samples and computes the branch metrics between the possible symbols between states and the received symbol. An ACS (Add-Compare-Select) unit 26 accumulates the branch metrics recursively as path metrics according to the trellis determined by the convolutional encoder polynomial. The most likely path is determined by a traceback unit 27 and a traceback memory 28 which receives information from the ACS unit 26. A trace-back unit 16 processes the decisions being made in the ACSU due to carrying out of the ACS recursion and outputs the estimated path, with a latency of trace-back depth. If a high speed Viterbi decoder needs to be implemented, the critical path of a Viterbi decoder must be minimized. It is obvious that the branch metric unit as well as the traceback unit and memory are purely feedforward and the throughput can be easily increased by massive pipelining. However, this does not hold for the ACS since the ACS has recursive arithmetic operations.

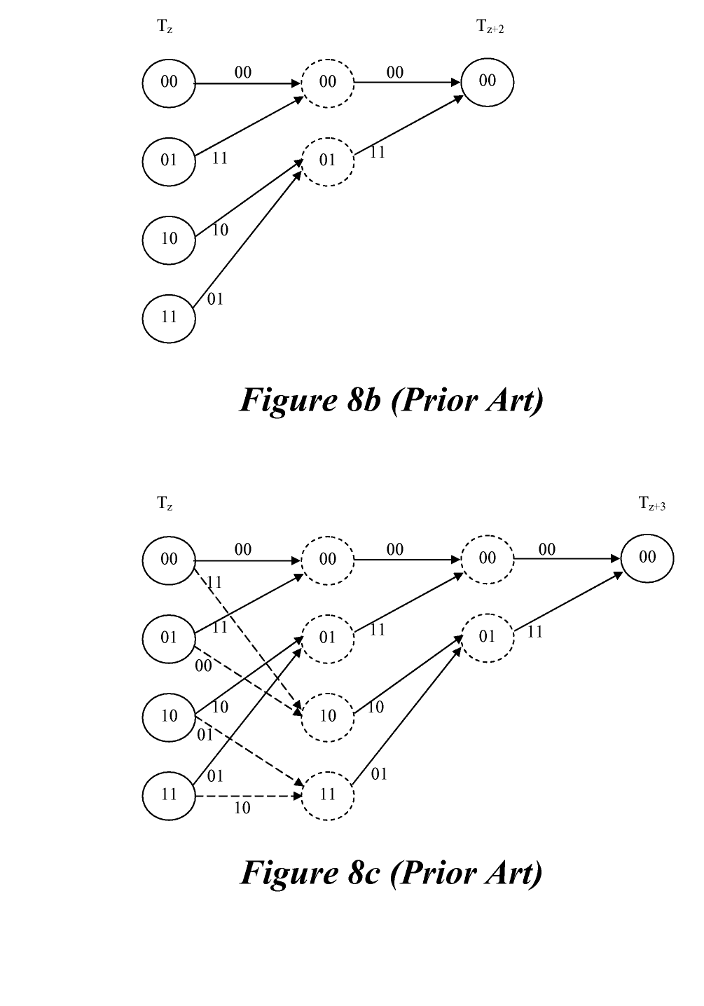

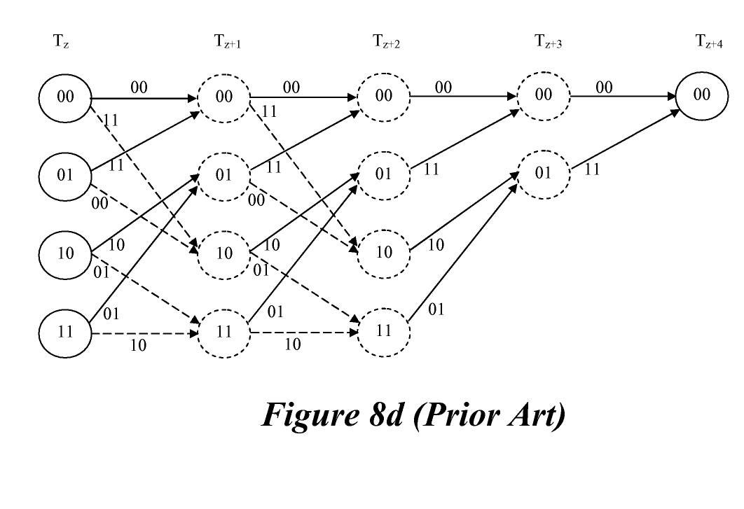

The ACS unit 26 contains a plurality of ACS sub-units. For each clock, an ACS sub-unit determines the path metrics at a given state and selects the optimal path. A Radix-2 ACS sub-unit selects one path from the previous clock (i.e., between times T_{z} and T_{z+1}). This is shown diagrammatically in FIG. 8a, where an ACS sub-unit at state “00” of time T_{z+1} selects one path from two nodes at T_{z}. In FIG. 8b, the function of a Radix-4 ACS sub-unit is shown, which selects a path from four nodes at T_{z}, where the four nodes are displaced by two clocks; i.e., node “00” at time T_{z+2} selects one path from the nodes at T_{z}. A Radix-4 ACS thus produces two information bits per clock cycle. The functions of Radix-8 and Radix-16 ACS sub-units are shown in FIGS. 8c and 8d, respectively. Each state in the trellis requires a separate sub-unit; hence, the ACS unit 26 would require four ACS sub-units to determine the optimal path through the trellis of FIG. 4. In general, a high-throughput Viterbi decoder instantiates 2^{K-1} ACS sub-units.

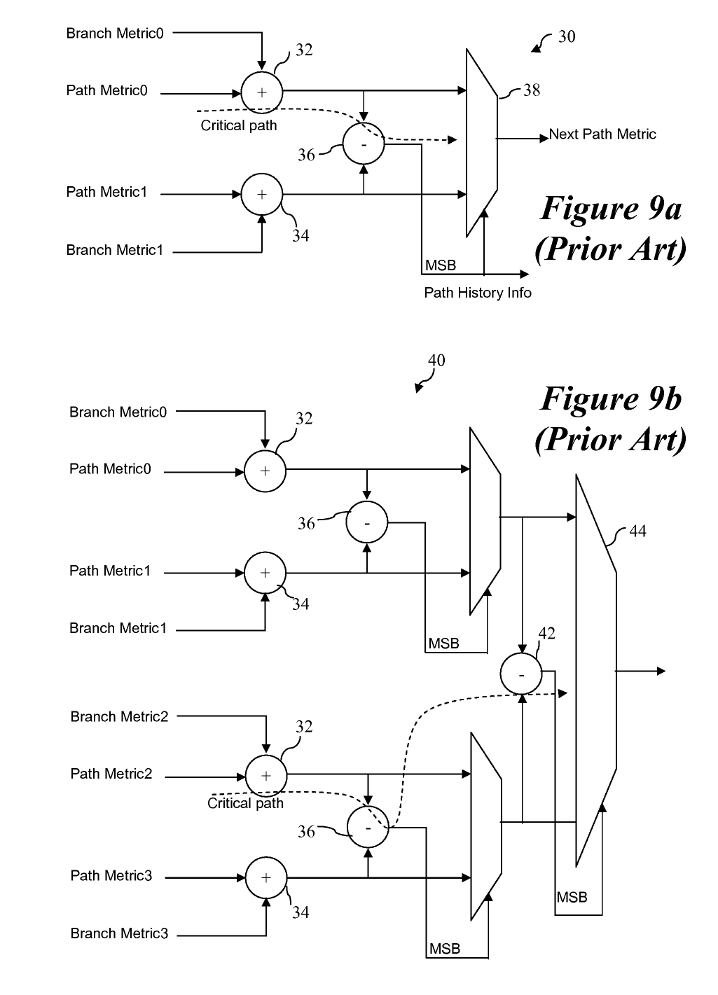

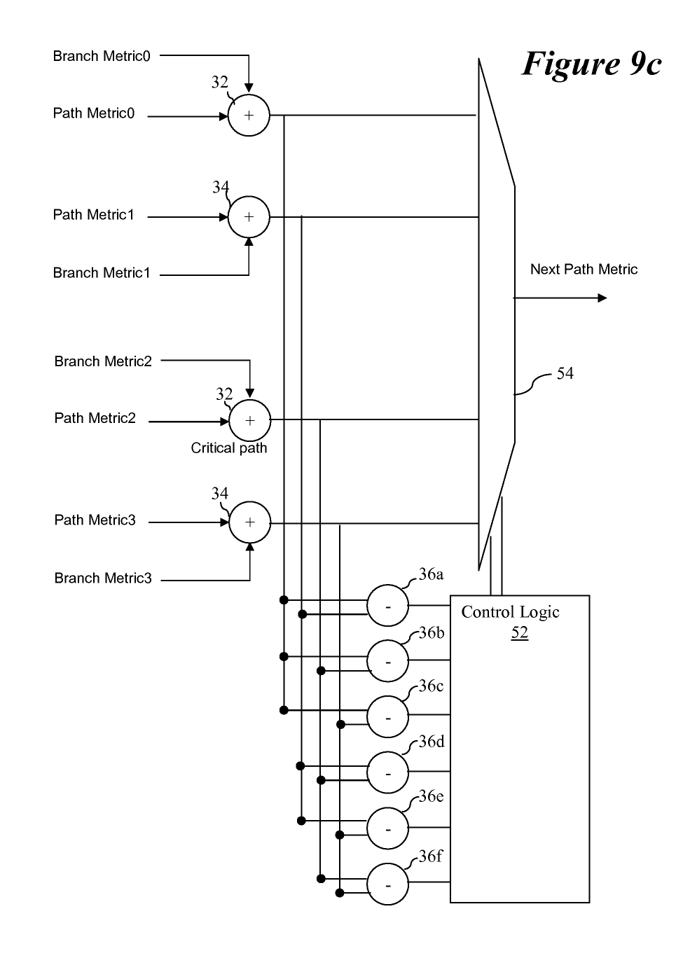

FIGS. 9a and 9b illustrate schematic representations of a conventional Radix-2 ACS sub-unit and a conventional Radix-4 ACS sub-unit 30, respectively. Referring to FIG. 9a, the Radix-2 ACS sub-unit has three adders; adders 32 and 34 sum the branch metric to a previous path metric and adder 36 subtracts one sum from the other. The MSB of the output of adder 36 (which indicates which of the sums is larger) controls a multiplexer 38 which passes the surviving path metric. The MSB is stored in the traceback memory 28. The critical path delay includes two adders (i.e., the data must propagate through two adders to select the surviving path).

FIG. 9b illustrates a Radix-4 ACS sub-unit 40. The Radix-4 ACS sub-unit unit 40 is similar to two Radix-2 units, with an additional adder 42 and multiplexer 44 to choose a path from between the outputs of adders 36. The critical path of Radix-4 ACS sub-unit 40 includes three adders.

FIG. 9c illustrates a Radix-4 “Fast” ACS sub-unit 50 where all path comparisons are made in parallel by adders 36a-f. This design allows the elimination of adder 42, and thus reduces the critical path to two adders, but increases the overall number of adders in the unit and requires a control logic unit 52 to determine the selected path. Control logic 52 selects an output through multiplexer 54. An ACS sub-unit of this type is described in connection with U.S. Ser. No. 10/322876, filed Dec. 18, 2002, entitled “High Speed Add-Compare-Select Circuit For Radix-4 Viterbi Decoder”, to Seok-Jun Lee and Manish Goel, and assigned to Texas Instruments incorporated, which is incorporated by reference herein. A similar architecture can be used for Radix-8 Fast ACS units and Radix-16 Fast ACS units.

Larger radix units can have a substantially longer critical path. Table I summarizes important criteria for various ACS types (where N represents the number of states for a given time period).

TABLE I
ACS Complexity

| | | No. of adders | No. of adders | |
|---|---|---|---|---|
| Architecture | Decoded | In Path Metric | in critical | |
| Type | Bits/clock | Unit | path | Adders/bit |
| Radix-2 | 1 | 3N | 2 | 1.5 |
| Radix-4 | 2 | 7N | 3 | 3.5 |
| Radix-4 fast | 2 | 10N | 2 | 5 |
| Radix-8 | 3 | 15N | 4 | 5 |
| Radix-8 fast | 3 | 18N | 3 | 6 |
| Radix-16 fast | 4 | 34N | 4 | 8.5 |
| Radix-16 fast2 | 4 | 52N | 3 | 13 |

In the table above, the adders/bit column indicates how many adders are used in the ACS unit 26 for each bit output per clock cycle. The present invention uses cascaded ACS units, which can be of any design, in order to improve the number of adders/bit relative to the speed of the ACS, which is substantially determined by the number of adders in the critical path.

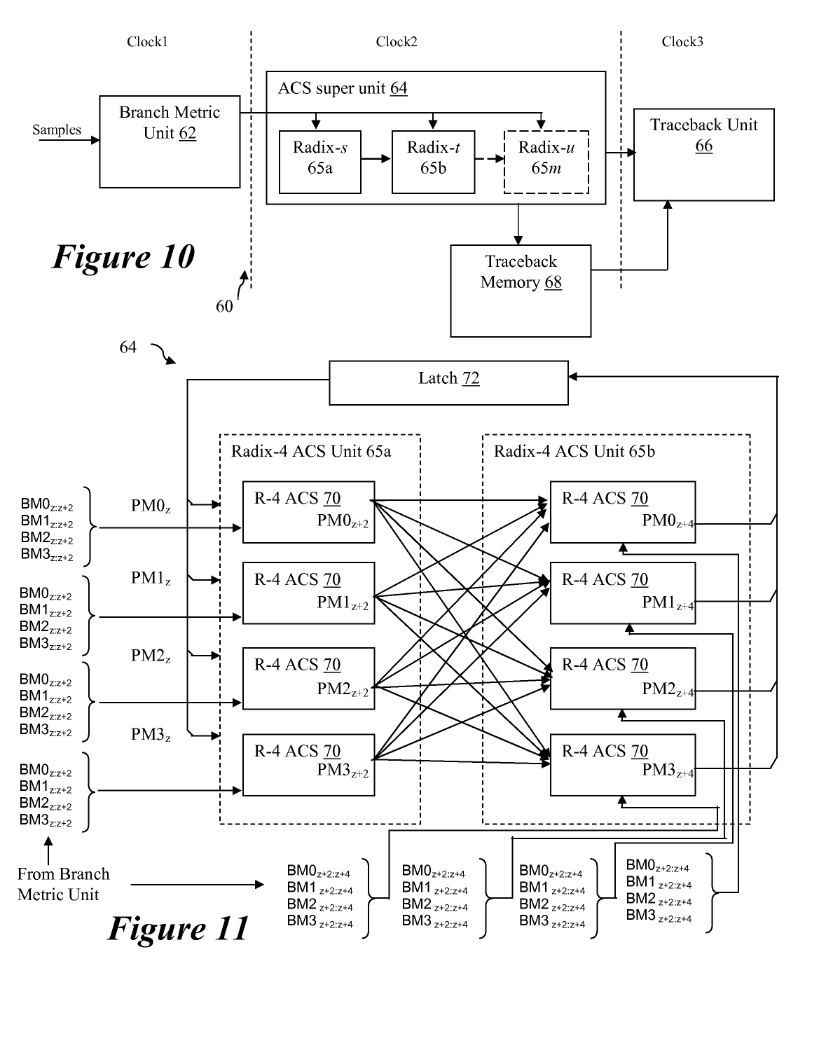

FIG. 10 illustrates a generalized block diagram a Viterbi decoder 60 of the present invention. A branch metric unit 62, similar to that shown in FIG. 7, computes branch metrics for a Cascaded ACS unit 64, which includes two or more cascaded ACS units 65 (individually referenced 65a, 65b, and 65m. The Cascaded ACS unit 64 is coupled to the traceback unit 66 and the traceback memory 66.

In operation, the Cascaded ACS unit 64 includes two or more ACS units similar to ACS unit 26 of FIG. 7. The branch metric unit 62 provides branch metrics to each of the ACS units 65; the branch metrics computed by the branch metric unit will depend upon the radix of the various ACS units 65, as described in more detail below.

On each clock, the path metric will be computed for a number of bits equal to log₂(s)+log₂(t)+log₂(u), where s, t, and u are the radix units of the various ACS units 65 (it being understood that there could be additional ACS units 65). For example, if two Radix-4 ACS units are used, then four bits will be calculated on each clock. In this case, the branch metric unit 62 would need to calculate, in each clock cycle, the branch metric between T_{z} and T_{z+2} (for an arbitrary starting point T_{z}) for each state of the first Radix-4 ACS unit 65a and the branch metric between T_{z+2} and T_{z+4} for each state of the second Radix-4 ACS unit 65b. If a Radix-4 and a Radix-8 ACS unit are used in the Cascaded ACS unit 64, then five bits will be calculated on each clock. In this case, the branch metric unit 62 would need to calculate the branch metric between T_{z} and T_{z+2} for each state of the Radix-4 ACS unit 65a and the branch metric between T_{z+2} and T_{z+5} for each state of the Radix-8 ACS unit 65b.

FIG. 11 illustrates a block diagram of an implementation using two Radix-4 ACS units 65, with each Radix-4 unit 65 using four Radix-4 ACS sub-units 70, such as those shown in connection with FIGS. 9b and 9c. Latch 72 stores the path metrics calculated in each clock cycle for adding to the branch metrics of the next clock cycle. For each ACS sub-unit in each ACS unit 65, the branch metric unit 62 provides four branch metrics. For example, for the ACS unit of FIG. 11, the branch metric unit 62 supplies the ACS sub-unit 70 in ACS unit 65a associated with state “00” with four branch metric units: BM0_{z:z+2}, BM1_{z:z+2}, BM2_{z:z+2}, and BM3_{z:z+2}, where BM0_{z:z+2} signifies the branch metric from state “00” at time T_{z} to state “00” at time T_{z+2}, BM1_{z:z+2} signifies the branch metric from state “01” at time T_{z} to state “00” at time T_{z+2}, and so on. Hence in FIG. 11, each ACS unit 65 receives sixteen branch metrics (four for each ACS sub-unit 70) on each clock cycle.

Advantageously, if, for example, Radix-4 fast ACS units were used for the ACS units 65 of FIG. 11, the critical path though both ACS units 65 would be four adders (two adders for each ACS unit 65). The total number of adders in the two ACS units would be eighty adders (ten for each sub-unit 70). Four bits would be processed by the Cascaded ACS unit 64 per clock cycle.

In contrast, a Radix 16 fast unit, which also processes four bits per clock cycle and also has four adders in its critical path, uses 136 adders, a substantial increase in complexity and die area. A comparison of various ACS complexity using cascaded ACS units is shown in Table II. Thus, the cascaded Radix-4 fast Cascaded ACS unit 64 uses five adders per bit produced each clock cycle whereas the Radix-16 ACS unit uses 8.5 adders per bit produced each clock cycle.

TABLE II
ACS Complexity Compared to Cascaded Radix-4 Architecture

| | | No. of adders | No. of adders | |
|---|---|---|---|---|
| Architecture | | In Path Metric | in critical | |
| Type | Bits/clock | Unit | path | Adders/bit |
| Radix-4 fast | 2 | 10N | 2 | 5 |
| Radix-8 | 3 | 15N | 4 | 5 |
| Radix-8 fast | 3 | 18N | 3 | 6 |
| Radix-16 fast | 4 | 34N | 4 | 8.5 |
| Radix-16 fast2 | 4 | 52N | 3 | 13 |
| Cascaded | 4 | 14N | 6 | 3.5 |
| Radix-4 | | | | |
| Cascaded | 4 | 20N | 4 | 5 |
| Radix-4 fast | | | | |

Unlike the geometric increase in gate count due to processing more bits per clock cycle by increasing the Radix of the ACS unit, cascading ACS units in an Cascaded ACS unit is a linear increase in gate count. Hence, the gate count of cascading three Radix-4 ACS units would triple the number of gates relative to a single Radix-4 ACS unit and would triple the number of bits processed per clock cycle.

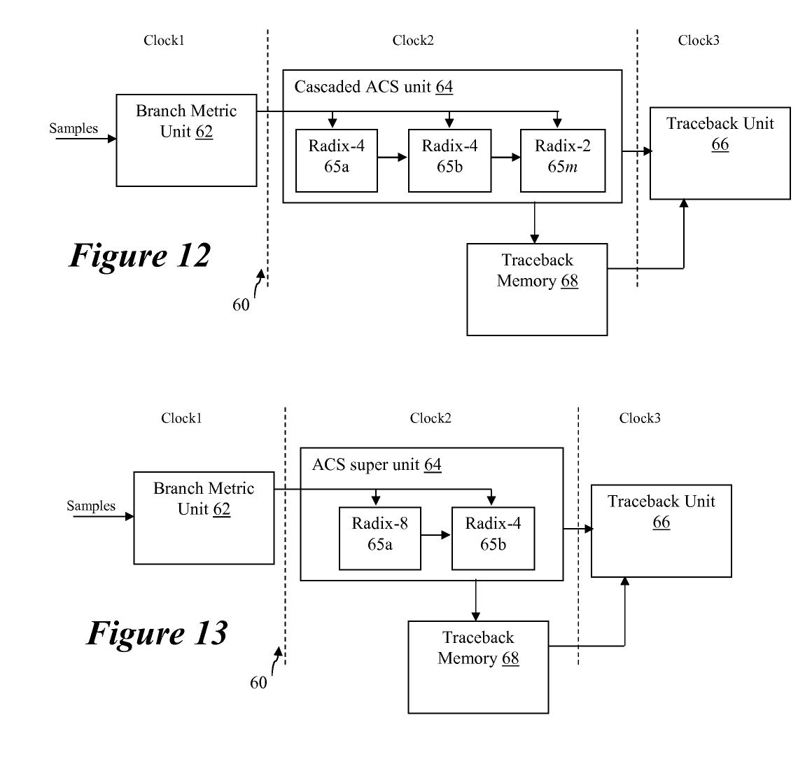

FIGS. 12 and 13 provide alternative implementations of a cascaded ACS architectures to produce five bits per clock cycle. In FIG. 12, the five bits are produced by cascaded Radix-4, Radix-4 and Radix-2 ACS units. This implementation has a six adder critical path. In FIG. 13, cascaded Radix-8 and Radix-4 ACS units are used to produce the five bits per clock cycle. This implementation has a five adder critical path.

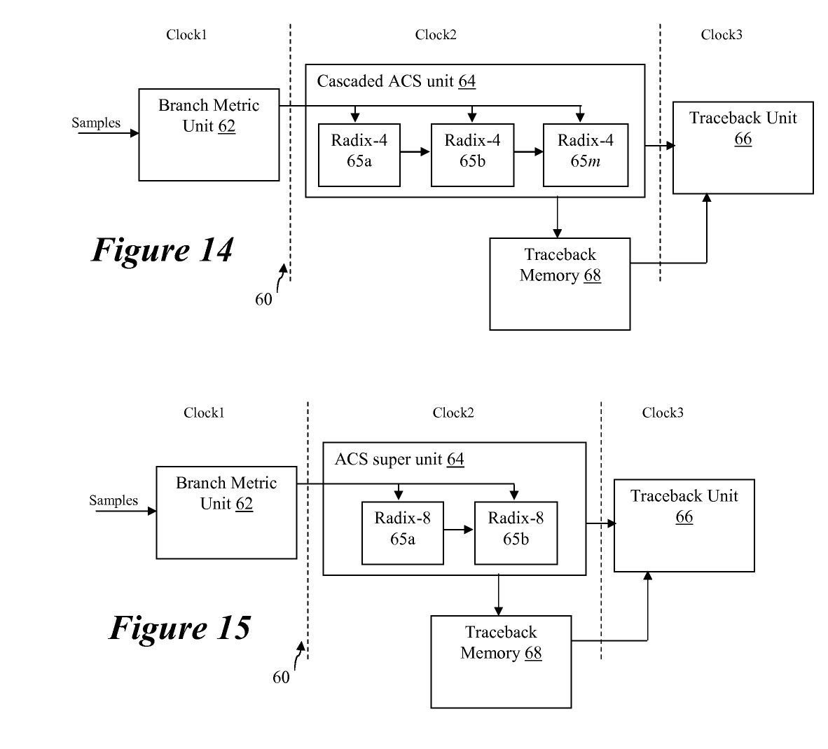

FIGS. 14 and 15 provide alternative implementations of a cascaded ACS architectures to produce six bits per clock cycle. In FIG. 14, the six bits are produced by three cascaded Radix-4 (fast) ACS units. This implementation has a six adder critical path. In FIG. 13, two cascaded Radix-8 (fast) ACS units are used to produce the six bits per clock cycle. This implementation also has a six adder critical path.

Accordingly, the present invention provides an architecture by which the number of bits of information processed per clock cycle by the Cascaded ACS unit can be increased without increasing the number of adders/bit processed per clock cycle. This can greatly reduce the cost and complexity of the Viterbi decoder.

Although the Detailed Description of the invention has been directed to certain exemplary embodiments, various modifications of these embodiments, as well as alternative embodiments, will be suggested to those skilled in the art. The invention encompasses any modifications or alternative embodiments that fall within the scope of the Claims.

1. A Viterbi decoder comprising:
a branch metric unit for generating branch metrics between two states at two different time periods;
a traceback unit;
a traceback memory; and
an add-compare-select circuit comprising a plurality of cascaded add-compare-select sub-circuits, each add-compare-select sub-circuit calculating a path metric responsive to a plurality of branch metrics from the branch metric unit and a plurality of pre-calculated path metrics, where at least one of the add-compare-select sub-circuits receives a set of pre-calculated path metrics from another one of the other add-compare-select sub-circuits.

2. The Viterbi decoder of claim 1 wherein the plurality of add-compare-select sub-circuits include at least one Radix-4 add-compare-select unit.

3. The Viterbi decoder of claim 1 wherein the plurality of add-compare-select sub-circuits include at least one Radix-2 add-compare-select unit.

4. The Viterbi decoder of claim 1 wherein the plurality of add-compare-select sub-circuits include at least one Radix-8 add-compare-select unit.

5. The Viterbi decoder of claim 1 wherein the plurality of add-compare-select sub-circuits include at least two add-compare-select sub-circuits.

6. The Viterbi decoder of claim 1 wherein the plurality of add-compare-select sub-circuits include at least three add-compare-select sub-circuits.

7. An add-compare-select circuit comprising:
a first add-compare-select sub-circuit for receiving a first set of path metrics calculated in a previous clock cycle and a set of branch path metrics and for generating a second set of path metrics; and
a second add-compare-select sub-circuit for generating a third set of path metrics from a second set of branch metrics and the second set of calculated path metrics from the first add-compare-select sub-circuit.

8. The add-compare-select of claim 7 and further comprising a third add-compare-select sub-circuit for generating a fourth set of path metrics from a third set of branch metrics and the third set of calculated path metrics from the second add-compare-select sub-circuit.

9. The add-compare-select of claim 7 wherein one the add-compare-select sub-circuits include at least one Radix-4 add-compare-select unit.

10. The add-compare-select of claim 7 wherein one the add-compare-select sub-circuits include at least one Radix-2 add-compare-select unit.

11. The add-compare-select of claim 7 wherein one the add-compare-select sub-circuits include at least one Radix-8 add-compare-select unit.

12. A method of performing a Viterbi decoding function comprising the steps of:
receiving a first set of path metrics calculated in a previous clock cycle and a first set of branch path metrics in a first add-compare-select sub-circuit and generating a second set of path metrics in the first add-compare-select sub-circuit; and
generating a third set of path metrics in a second add-compare-select sub-circuit from a second set of branch metrics and the second set of calculated path metrics from the first add-compare-select sub-circuit.

13. The method of claim 12 and further comprising the step of generating a fourth set of path metrics in a third add-compare-select sub-circuit from a third set of branch metrics and the third set of calculated path metrics from the second add-compare-select sub-circuit.
